(19) United States
(12) Patent Application Publication
(10) Pub. No.: US 2025/0329667 A1
(43) Pub. Date: Oct. 23, 2025

(54) ELECTRONIC CHIP AND METHOD

(71) Applicant: STMicroelectronics International N.V., Geneva (CH)

(72) Inventors: Pascal Fornara, Pourrières (FR); Julien Amouroux, Aix en Provence (FR)

(21) Appl. No.: 19/077,787

(22) Filed: Mar. 12, 2025

(30) Foreign Application Priority Data
Apr. 18, 2024 (FR) FR2404017

(51) Int. Cl. H01L 23/58; H01L 21/71; H01L 23/00; H01L 23/528

(52) U.S. Cl. CPC H01L 23/585; H01L 21/71; H01L 23/528; H01L 23/562

(57) ABSTRACT

The present description concerns an electronic chip delimited by an edge and comprising a semiconductor layer extending along a main plane, an interconnection structure positioned above the semiconductor layer, and a seal ring arranged in the interconnection structure between the edge of the electronic chip and an electronic circuit region of the electronic chip. The seal ring comprises a plurality of cavities coupled together to form at least one continuous ring-shaped cavity around the electronic circuit region, and/or a plurality of conductive regions coupled together to form at least one conductive ring-shaped wall around the electronic circuit region.

### CROSS-REFERENCE TO RELATED APPLICATIONS

This application claims priority to French Application No. 2404017, filed on Apr. 18, 2024, which application is hereby incorporated herein by reference.

### TECHNICAL FIELD

The present disclosure generally concerns electronic chips, or integrated circuits, and associated methods, and in particular electronic chips comprising seal rings and associated methods.

### BACKGROUND

In industry, most electronic devices are manufactured in series. Generally, a plurality of copies of an electronic device are simultaneously manufactured inside and on top of a same semiconductor substrate, for example a same semiconductor wafer. In particular, a plurality of electronic chips are generally manufactured inside and on top of a same semiconductor substrate, for example a same semiconductor wafer. The electronic chips can then be separated, or singulated, so that they can be used, for example, alone or in a more complete electronic device. This singulation is generally performed by cutting.

During this singulation, for example during a cutting of the semiconductor wafer, a crack may appear on an edge of an electronic chip. Such a crack may lead to a failure of the electronic circuits of the electronic chip.

Further, even if cracks do not appear during the manufacturing, certain cracks may appear during the lifetime of the chip, in particular on an edge of the chip, for example due to changes in the electronic chip temperature.

To protect an electronic chip, in particular during the manufacturing, the singulation, or even during its lifetime, the electronic chip may comprise a seal ring at its periphery. An object of the seal ring is to prevent the propagation of cracks from the edge to an electronic circuit region, or circuit region, of the electronic chip. However, the seal ring does not always prevent the forming and the propagation of cracks in the electronic chip.

It would be desirable to be able to improve, at least partly, electronic chips, and in particular the protection of electronic chips.

### SUMMARY

There exists a need for an electronic chip which is better protected, especially better protected from cracks.

It would be advantageous for the method of manufacturing such an electronic chip to be able to be carried out with conventional electronic chip manufacturing processes.

An embodiment overcomes all or part of the disadvantages of known electronic chips.

An embodiment provides a chip delimited by an edge, the electronic chip comprising: a semiconductor layer extending along a main plane; an interconnection structure positioned above the semiconductor layer; a seal ring arranged in the interconnection structure between the edge of the electronic chip and an electronic circuit region of the electronic chip, the seal ring comprising: a plurality of cavities coupled together so as to form at least one continuous ring-shaped cavity around the electronic circuit region; and/or a plurality of conductive regions coupled together so as to form at least one conductive ring-shaped wall around the electronic circuit region.

The electronic circuit region comprises electronic circuits formed inside and on top of the semiconductor layer.

According to an embodiment, the interconnection structure comprises: a plurality of metallization levels each comprising a conductive layer, the conductive layers of two successive metallization levels being coupled together by conductive vias and/or conductive strips of the interconnection structure; and insulating layers in which the conductive layers, and the conductive vias and/or the conductive strips are embedded; the interconnection structure being for example coupled to the semiconductor layer by means of another conductive via and/or of an electrical contact.

According to an embodiment, each metallization level of the interconnection structure comprises conductive elements of a conductive layer insulated from one another by insulating elements of an insulating layer.

According to an embodiment, the cavities and/or the conductive regions extend at least all the way to a first metallization level of the interconnection structure.

According to an embodiment, the cavities and/or the conductive regions extend at least all the way to an interface level between conductive vias and conductive layers of two successive metallization levels of the interconnection structure, for example all the way to an interface level between conductive vias and conductive layers of first and second metallization levels of the interconnection structure.

According to an embodiment, the cavities and/or the conductive regions extend all the way to the semiconductor layer.

According to an embodiment, the cavities and/or the conductive regions end at a non-zero distance from the semiconductor layer.

According to an embodiment, the conductive regions are metal regions, for example comprise tungsten, or are predominantly made of tungsten.

According to an embodiment, the seal ring comprises a sealing element comprising a conductive ring-shaped plate in each metallization level of the interconnection structure, two conductive ring-shaped plates of two successive metallization levels being coupled together in a direction perpendicular to the main plane by a conductive ring-shaped strip.

According to an embodiment, the at least one continuous ring-shaped cavity comprises a first continuous ring-shaped cavity between the electronic circuit region and the sealing element and/or a second continuous ring-shaped cavity between the sealing element and the edge of the electronic chip.

According to an embodiment, the at least one conductive ring-shaped wall comprises a first conductive ring-shaped wall between the electronic circuit region and the sealing element and/or a second conductive ring-shaped wall between the sealing element and the edge of the electronic chip.

According to an embodiment, the electronic chip further comprises, in the electronic circuit region, other cavities coupled together, and/or other conductive regions coupled together, between two adjacent conductive elements of the interconnection structure.

An embodiment provides a method of manufacturing an electronic chip, the method comprising: the provision of a structure comprising a semiconductor layer and a first metallization level of a future interconnection structure over the semiconductor layer, the structure comprising an electronic circuit region which comprises electronic circuits formed inside and on top of the semiconductor layer, and a seal ring region around the electronic circuit region, and the first metallization level comprising conductive elements of a conductive layer insulated from one another by insulating elements of a first insulating layer; the forming of first ports in the seal ring region through the first insulating layer between two adjacent conductive elements among the conductive elements; the widening of the first ports by etching, so as to form in the seal ring region open cavities coupled together around the electronic circuit region; the forming of a second insulating layer over the open cavities and the first insulating layer, so as to close the open cavities, forming cavities coupled together around the electronic circuit region, the cavities coupled together forming at least one continuous ring-shaped cavity around the electronic circuit region.

According to an embodiment, the method comprises, prior to the forming of the first ports, the deposition of a protection layer over the first insulating layer and the conductive elements, followed by the forming of openings by etching in the protection layer, the first ports being formed in line with the openings.

According to an embodiment, the method further comprises: the forming of at least two second ports by etching in the second insulating layer all the way to at least two of the cavities in the seal ring region; and the filling of the second ports with a conductive material, for example a metallic material, the filling of the second ports being performed so as to fill the cavities, forming conductive regions coupled together, and thus at least one conductive ring-shaped wall around the electronic circuit region.

According to an embodiment, the filling of the second ports also forms first conductive vias coupled to the conductive ring-shaped wall.

According to an embodiment, the method further comprises: the forming of third ports by etching in the second insulating layer, each third port extending all the way to one of the conductive elements; and the filling of the third ports with a conductive material, for example a metallic material, forming second conductive vias coupled to the conductive elements.

According to an embodiment, the forming of the third ports is performed at the same time as the forming of the second ports, and/or the filling of the third ports is performed at the same time as the filling of the second ports.

According to an embodiment, the method further comprises the forming, in the electronic circuit region, of other cavities coupled together and/or of other conductive regions coupled together, between two adjacent conductive elements of the interconnection structure.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A is a simplified and partial top view illustrating an example of an electronic chip;

FIG. 1B is a simplified and partial cross-section view showing an example of embodiment of the electronic chip of FIG. 1A;

FIG. 1C is another simplified and partial cross-section view of the electronic chip of FIG. 1B;

FIG. 2A is a simplified and partial top view illustrating an electronic chip according to an embodiment;

FIG. 2B is a simplified and partial cross-section view showing an example of embodiment of the electronic chip of FIG. 2A;

FIG. 2C is another simplified and partial cross-section view of the electronic chip of FIG. 2B;

FIG. 3A is a simplified and partial top view illustrating an electronic chip according to another embodiment;

FIG. 3B is a simplified and partial cross-section view showing an example of embodiment of the electronic chip of FIG. 3A;

FIG. 3C is another simplified and partial cross-section view of the electronic chip of FIG. 3B;

FIG. 4A, FIG. 4B, FIG. 4C, FIG. 4D, FIG. 4E, FIG. 4F, FIG. 4G, and FIG. 4H are cross-section views schematically and partially showing structures obtained at the end of steps of an example of a method of manufacturing an electronic chip according to an embodiment; and

FIG. 5A and FIG. 5B are cross-section views schematically and partially showing structures obtained at the end of steps of a variant of the manufacturing method of FIGS. 4A to 4H.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the manufacturing steps and the details of the electronic chips are described, since they can be formed with usual electronic chip manufacturing methods. In particular, the electronic circuits of the electronic chips are not shown, the embodiments being compatible with different electronic circuits in an electronic chip. Further, not all the manufacturing steps and the details of the interconnection structures are described, since they can be formed with usual interconnection structure manufacturing methods.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively signify, unless otherwise specified, electrically insulating and electrically conductive.

In the following description, unless otherwise specified, when reference is made to a chip, it is referred to an electronic chip, when reference is made to a via, it is referred to a conductive via, and when reference is made to a substrate, it is referred to a semiconductor substrate.

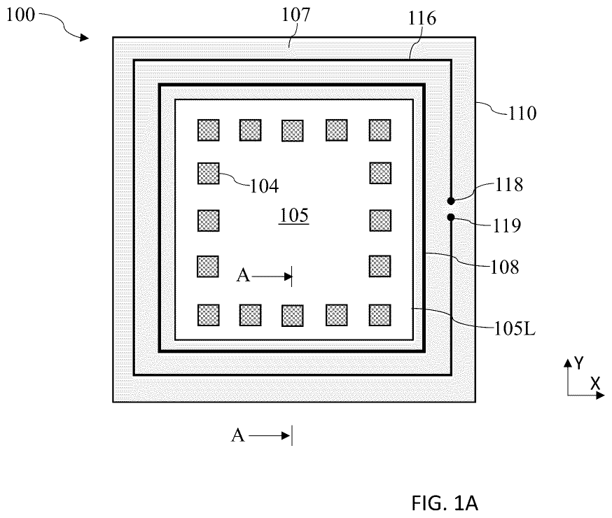

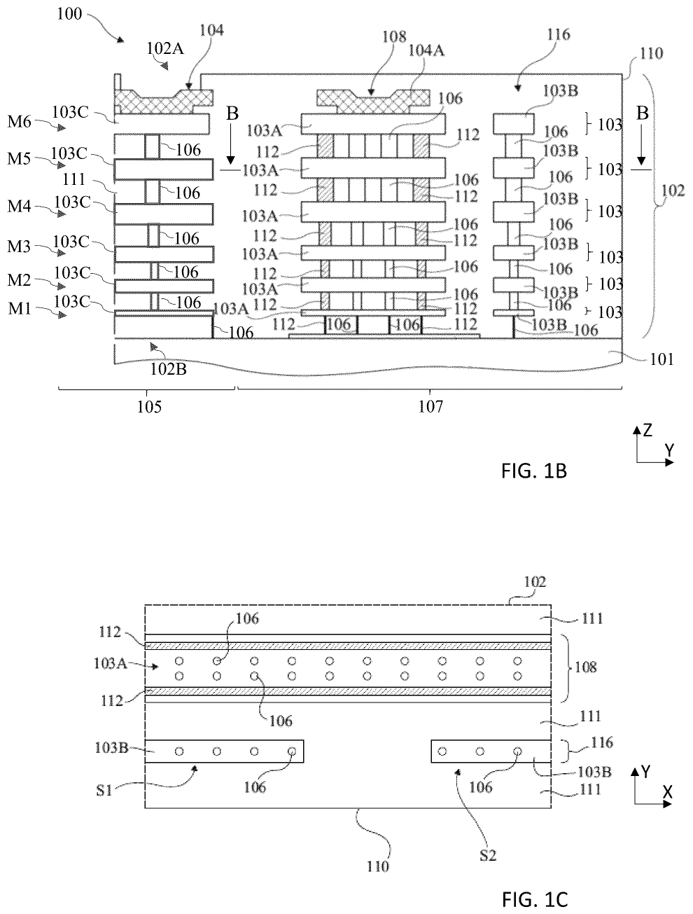

In FIGS. 1A to 3C described in the following, an electronic chip which has already been singulated is shown. However, in practice, the entire following description of the chip also applies when the chip has not been singulated yet and still forms part of a semiconductor wafer comprising, for example, a plurality of chips. In particular, in the case where the chip still forms part of a semiconductor wafer, the chip edge corresponds to the location of the chip edge after the singulation step. By edge, there is meant all the edges, or peripheral ends, of the chip.

FIG. 1A is a simplified and partial top view illustrating an example of an electronic chip 100. FIG. 1B is a simplified and partial cross-section view showing an example of embodiment of the electronic chip 100 of FIG. 1A. FIG. 1C is another simplified and partial cross-section view of the electronic chip of FIG. 1B. The cross-section view of FIG. 1B is obtained along the cross-section plane A-A indicated in FIG. 1A. The cross-section view of FIG. 1C is obtained along the cross-section plane B-B indicated in FIG. 1B.

Chip 100 comprises a semiconductor layer 101, for example corresponding to a semiconductor substrate, for example made of silicon, or to the semiconductor layer of a substrate of silicon-on-insulator, or SOI type. The electronic circuits of chip 100 are arranged inside and/or on top of semiconductor layer 101. The electronic circuits of chip 100 are not shown in FIGS. 1A, 1B, and 1C, but are all arranged in an electronic circuit region 105, or circuit region, of chip 100 delimited by circumference 105L. In other words, circuit region 105 comprises all the electronic circuits of chip 100. The circuit region 105 of chip 100 is, for example, a central region of chip 100, as shown in the view of FIG. 1A.

Chip 100 further comprises an interconnection structure 102 above semiconductor layer 101, for example in contact with semiconductor layer 101. This interconnection structure 102 is also designated with the expression “back-end-of-line interconnection structure”, or “BEOL” interconnection structure to make it short. Interconnection structure 102 comprises a plurality of metallization levels. Six metallization levels M1, M2, M3, M4, M5, M6 have been shown in the example of FIG. 1B, although this is not limiting, since the number of metallization levels may vary.

Each metallization level comprises at least a portion 103C of a conductive layer 103, for example a metal layer, each portion 103C forming a conductive element in the form of a conductive track, or conductive line. The conductive tracks 103C of the different levels of interconnection structure 102 are electrically coupled to each other, and/or to connection pads 104, and/or to the electronic circuits of chip 100 by conductive vias 106, for example metal vias. The conductive tracks 103C of the various levels of interconnection structure 102 are preferably positioned in circuit region 105. Thus, interconnection structure 102 enables to couple the electronic circuits of chip 100 to each other and/or to connection pads 104. It is considered that the connection pads 104, which may be referred to as “pads” to make it short, form part of interconnection structure 102. Pads 104 are arranged at the upper metallization level of interconnection structure 102 in the example of FIG. 1B, which corresponds to metallization level M6. In other words, pads 104 are arranged on an upper surface 102A (first surface) of interconnection structure 102, a lower surface 102B (second surface) of the interconnection structure, opposite to upper surface 102A, being in contact with semiconductor layer 101.

Pads 104 are distributed in a substantially ring-shaped manner, here a square-shaped ring, in the circuit region 105 of chip 100 and, more precisely, in a region of the interconnection structure 102 contained in the circuit region 105 of chip 100.

Pads 104 are configured to be in contact with conductive elements located outside of chip 100, so that chip 100 can, for example, exchange electrical signals with the outside. For example, each pad 104 is in direct contact with a conductive track 103C of upper metallization level M6, that is, the metallization level which is most distant from semiconductor layer 101. Interconnection structure 102 further comprises insulating layers, which are all designated with a same and unique reference numeral 111 in FIGS. 1B and 1C, which each separate two successive metallization levels and which may also be between portions of each conductive layer 103 at a same metallization level, conductive layers 103 and vias 106 being embedded in insulating layers 111. The insulating layers as a whole may be designated as being an insulating layer. The insulating layer may be made of an oxide, for example a silicon oxide, or of a dielectric material of high-K type, that is, a material having a high dielectric constant k as compared with that of silicon dioxide.

Chip 100 comprises a sealing region 107, or seal ring, at the periphery of chip 100, that is, between circuit region 105 and the edge 110 of chip 100. Thus, seal ring 107 surrounds the circuit region 105 of chip 100. Seal ring 107 is ring-shaped in top view. Seal ring 107 is arranged in interconnection structure 102, at the periphery of chip 100. Seal ring 107 thus forms part of interconnection structure 102, although it is not used to connect the electronic circuits of chip 100 together and/or to pads 104. Preferably, chip 100 comprises no electronic circuits in seal ring 107. In other words, the circuit region 105 of chip 100 is laterally delimited, in interconnection structure 102, by seal ring 107.

A targeted function of seal ring 107 is to avoid the propagation of cracks from the edge 110 of chip 100 to the circuit region 105 of chip 100.

Another targeted function of seal ring 107 may be to block the propagation of moisture from the outside of chip 100, and thus from the edge 110 of chip 100, to the electronic circuits of the circuit region 105 of chip 100.

To perform one or a plurality of these functions, seal ring 107 may comprise one or a plurality of sealing elements 108, each sealing element having a ring shape in top view. One sealing element has been shown in FIGS. 1A, 1B, and 1C, although there may be a plurality thereof, as indicated hereafter. When there are a plurality of sealing elements, they may be substantially concentric. A sealing element may be adapted to stopping the propagation of cracks, another sealing element may be adapted to blocking moisture ingress, and/or a sealing element may be adapted to performing these two functions of stopping crack propagation and of blocking moisture ingress. Each sealing element extends in height from semiconductor layer 101 across all or part of the metallization levels M1-M6 of interconnection structure 102, for example across one or a plurality of lower metallization levels of interconnection structure 102. For moisture protection, it is however preferable for sealing element 108 to extend all the way to upper metallization level M6.

The shown sealing element 108 forms a closed loop around the circuit region 105 of chip 100, or, in other words, sealing element 108 fully surrounds the circuit region 105 of chip 100.

In the embodiment shown in FIG. 1B, sealing element 108 forms a ring-shaped wall comprising other portions 103A of the conductive layers 103 of interconnection structure 102. More specifically, sealing element 108 comprises a portion 103A of the conductive layer 103 of each metallization level M1-M6 of interconnection structure 102. Each portion 103A of conductive layer 103 forms a conductive ring-shaped plate at each metallization level. For example, each conductive ring-shaped plate 103A extends in a plane substantially parallel to semiconductor layer 101. The successive conductive ring-shaped plates 103A of sealing element 108 are coupled together by one or a plurality of conductive ring-shaped strips 112 which extend continuously between two successive conductive ring-shaped plates 103A. In other words, conductive ring-shaped strips 112 join two successive conductive ring-shaped plates 103A in the Z direction perpendicular to the XY plane of semiconductor layer 101.

As shown in FIG. 1B, the successive conductive ring-shaped plates 103A of sealing element 108 may further be coupled together by conductive vias 106 of interconnection structure 102, enabling for example to increase the mechanical resistance of sealing element 108 to the propagation of cracks. Vias 106 may be cylindrical, as shown in FIG. 1C. As variants, the vias may be elongated in the form of bars, or even form the conductive ring-shaped strips 112. Vias 106 and conductive ring-shaped strips 112 may be formed during a same manufacturing step.

Sealing element 108 may form a wall of protection against the propagation of moisture towards the circuit region 105 of chip 100.

As shown in FIG. 1B, seal ring 108 may comprise a dummy pad 104A, which is for example formed at the same time as pads 104. Dummy pad 104A rests on conductive ring-shaped plate 103A at the upper metallization level M6 of interconnection structure 102. Dummy pad 104A may be arranged substantially in a ring, here it forms a square-shaped ring. It may be a plurality of dummy pads. The ring-shaped arrangement and the presence of one or a plurality of dummy pads is not mandatory.

In order to detect cracks in chip 100, seal ring 107 may comprise a crack sensor 116, or crack detector. Crack sensor 116 is arranged in interconnection structure 102. In other words, interconnection structure 102 comprises crack sensor 116. As shown in FIGS. 1A, 1B, and 1C, crack sensor 116 may be arranged in a region located between the edge 110 of chip 100 and sealing element 108, this region of interconnection structure 102 comprising no other sealing element. Thus, if a crack appears at the edge 110 of chip 100 and propagates towards circuit region 105, the crack can be detected by crack sensor 116 before sealing element 108. Other configurations may be envisaged, as described hereafter.

Crack sensor 116 corresponds to a conductive structure which forms a conductive path, preferably an open loop. By testing the electrical conductivity between a first terminal, or node, 118 of sensor 116, for example a first end of sensor 116, and a second terminal, or node, 119 of sensor 116, for example a second end of sensor 116, cracks can be detected by sensor 116.

In the example of embodiment shown in FIGS. 1B and 1C, crack sensor 116 comprises a plurality of metal stacks, each comprising other portions 103B of the conductive layers 103 coupled by conductive vias 106 of interconnection structure 102. More specifically, each metal stack extends in height in the Z direction perpendicular to the XY plane of semiconductor layer 101 through all or part of the metallization levels M1-M6 of interconnection structure 102, in the shown example all the way to upper metallization level M6. There have been illustrated as an example in FIG. 1C two metal stacks S1 and S2 of crack sensor 116, although there may be more than two.

Preferably, although this is not illustrated in FIGS. 1B and 1C, in each metallization level, the portions 103B of crack sensor 116 are discontinuous to form an electrical path extending upwards and downwards in crack sensor 116 by means of the vias 106 of crack sensor 116 which form a chain of vias. Preferably, crack sensor 116 comprises a plurality of portions 103B in each metallization level of interconnection structure 102.

Although this is not shown in FIGS. 1A, 1B, and 1C, seal ring 107 may comprise a plurality of sealing elements similar to the above-described sealing element 108, for example an inner sealing element arranged in interconnection structure 102 around circuit region 105 and an outer sealing element arranged in interconnection structure 102 around the inner sealing element. Seal ring 107 may then comprise an intermediate crack sensor, for example similar to the previously-described crack sensor 108, arranged in interconnection structure 102 between the inner sealing element and the outer sealing element. The presence of inner and outer sealing elements and of an intermediate crack sensor between these inner and outer sealing elements enables to detect that cracks have propagated from the edge of the electronic chip across the outer sealing element.

Although this is not shown in FIGS. 1A, 1B, and 1C, seal ring 107 may comprise an inner crack sensor arranged in interconnection structure 102 around, or on the edges of, circuit region 105 and surrounded by sealing element 108, or of the inner sealing element. The inner crack sensor enables to detect that cracks have propagated from the edge 110 of chip 100 through the sealing element(s) and may reach circuit region 105.

More generally, any seal ring structure may be envisaged in the interconnection structure, aiming at limiting the propagation of cracks to the circuit region of the electronic chip, or even at blocking moisture. For example, the seal ring may comprise one or a plurality of sealing elements which do not necessarily extend all the way to the upper metallization level, or even a plurality of sealing elements which extend all the way to different metallization levels. For moisture protection, a sealing element preferably extends all the way to the upper metallization level. Further, the seal ring may comprise one or a plurality of crack sensors which do not necessarily extend all the way to the upper metallization level, or even a plurality of crack sensors which extend all the way to different metallization levels.

In certain cases, it has been observed by crack sensors, in particular by an inner crack sensor, that cracks can propagate in the seal ring, or even cross the seal ring. Thus, the seal ring is not always sufficient to stop cracks, that may propagate in the circuit region of the electronic chip.

The inventors provide an electronic chip enabling to meet the above-described improvement needs, and to overcome all or part of the disadvantages of the previously-described electronic chips. In particular, the inventors provide an electronic chip with an enhanced protection, in particular against cracks, in particular an electronic chip comprising a seal ring with an enhanced protection.

It would be advantageous for the method of manufacturing such an electronic chip to be implementable with conventional electronic chip manufacturing processes.

Embodiments of electronic chips will be described hereafter. The described embodiments are non-limiting and different variants will occur to those skilled in the art based on the indications of the present disclosure.

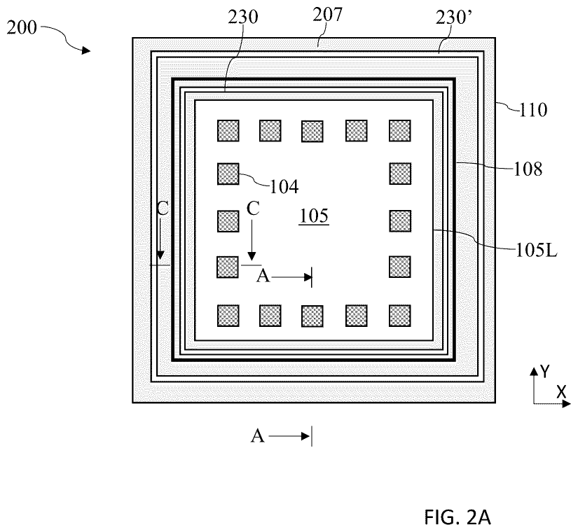

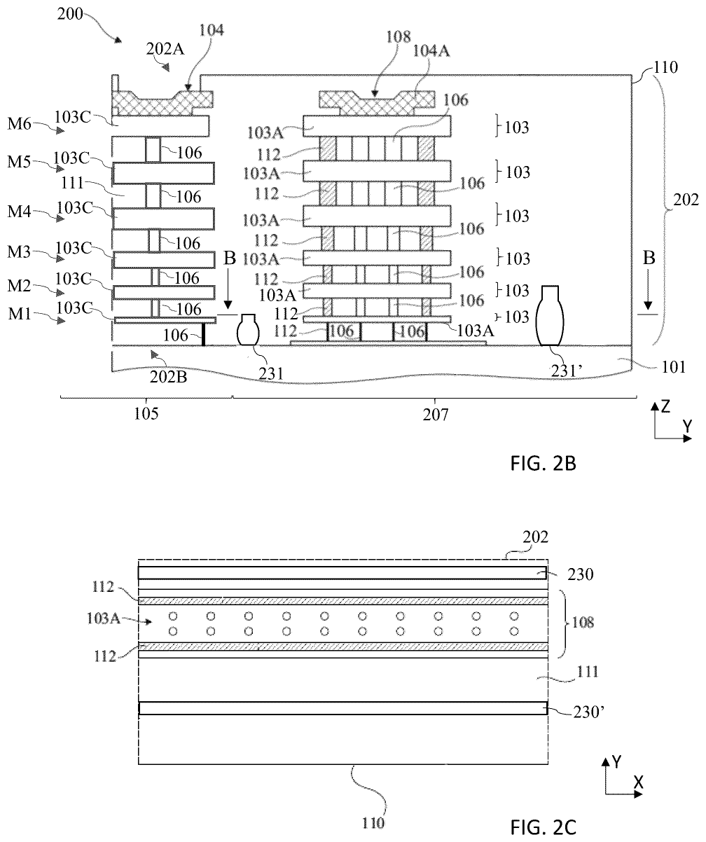

FIG. 2A is a simplified and partial top view illustrating an electronic chip 200 according to an embodiment. FIG. 2B is a simplified and partial cross-section view showing an example of embodiment of the electronic chip of FIG. 2A. FIG. 2C is another simplified and partial cross-section view of the electronic chip of FIG. 2B. The cross-section view of FIG. 2B is obtained along the cross-section plane A-A indicated in FIG. 2A. The cross-section view of FIG. 2C is obtained along the cross-section plane B-B indicated in FIG. 2B.

The electronic chip 200 of FIGS. 2A, 2B, and 2C has many features in common with the electronic chip 100 of FIGS. 1A, 1B, and 1C, and only the differences between the two electronic chips 100 and 200 are detailed in the following description.

The electronic chip 200 of FIGS. 2A, 2B, and 2C differs from the electronic chip 100 of FIGS. 1A, 1B, and 1C mainly in that seal ring 207 further comprises a plurality of cavities 231, 231′ in interconnection structure 202.

Cavities 231 are coupled together, forming a continuous ring-shaped cavity 230 which is located around circuit region 105, preferably all around circuit region 105, for example between circuit region 105 and sealing element 108. For example, continuous ring-shaped cavity 230 may be positioned in insulating layer 111 between the portions 103A, 103C of the conductive tracks 103 of one or a plurality of metallization levels.

Insulating layer 111 may be made of an oxide, for example a silicon oxide, or of a dielectric material of high-k type, that is, a material having a high dielectric constant k as compared with that of silicon dioxide.

Cavities 231′ are coupled together, forming a continuous ring-shaped cavity 230′ which is located around circuit region 105, preferably all around circuit region 105, for example between the edge 110 of chip 200 and sealing element 108.

The cavities can be referred to as “air gaps”. By cavity, there is meant a volume filled with a gas. Thus, the cavities are filled with gas, for example with air.

Such a continuous ring-shaped cavity enables to form a crack absorption region, thus preventing the propagation of cracks across seal ring 207 to circuit region 105.

Advantageously, the cavities 231, 231′ extend at least all the way to the interface between the vias 106 and the conductive layers 103 of two successive metallization levels, for example of the first metallization level M1 and of the second metallization level M2, so as to block the progression of cracks which would form or propagate at this interface.

There have been shown as an example cavities 231 which extend all the way to the first metallization level M1, thus forming a continuous ring-shaped cavity 230 in seal ring 207 at the first metallization level M1. When there is indicated up to a metallization level, it should be understood that this metallization level is included. As cracks often occur at the first metallization level, such a configuration may be sufficient to prevent the propagation of cracks all the way to the circuit region 105 of electronic chip 200. Further, this enables not to burden the electronic chip manufacturing method, knowing that it can be based on an air gap forming process, which may already be provided in another region of the interconnection structure, for example in circuit region 105, for example at the first metallization level M1.

But this example is not limiting, and there may be formed cavities 231′ which extend all the way to the second metallization level M2 as illustrated, or even all the way to a higher metallization level, or even to the upper metallization level (M6 in the shown example), thus forming a continuous ring-shaped cavity 230′ in seal ring 207, which extends beyond the first metallization level M1.

Further, there have been shown cavities 231, 231′ which reach semiconductor layer 101, which is not always necessary. As a variant, the cavities may be at a non-zero distance from semiconductor layer 101, for example end in insulating layer 111, which can form a more robust structure than with cavities 231, 231′ which end at the semiconductor layer 101.

The other features described in relation with FIGS. 1A, 1B, and 1C may apply to the electronic chip 200 of FIGS. 2A, 2B, and 2C.

In particular, in FIGS. 2A, 2B, and 2C, a single sealing element 108 has been shown, knowing that seal ring 207 may comprise a plurality of sealing elements in interconnection structure 202. For example, seal ring 207 may comprise one or a plurality of sealing elements which do not extend all the way to the upper metallization level, or even a plurality of sealing elements which extend all the way to different metallization levels. For moisture protection, a sealing element preferably extends all the way to the upper metallization level. Further, in FIGS. 2A, 2B, and 2C, no crack sensor has been shown, but the seal ring 207 of the chip 200 could comprise one or a plurality of crack sensors, similarly to what has been described in relation with FIGS. 1A, 1B, and 1C. Further, seal ring 207 could comprise one or a plurality of crack sensors which do not necessarily extend all the way to the upper metallization level, or even a plurality of crack sensors which extend all the way to different metallization levels.

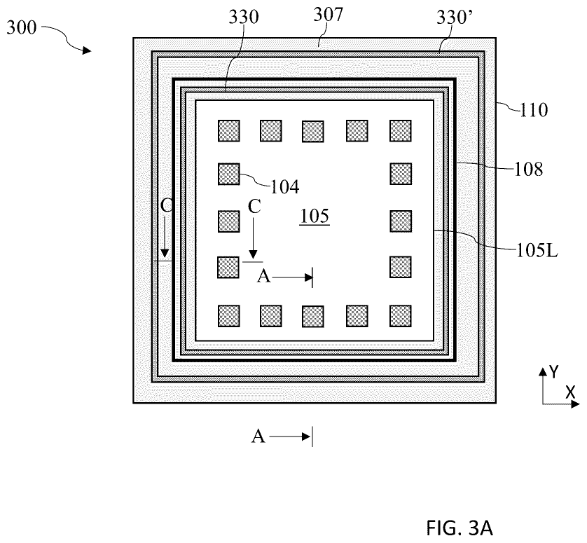

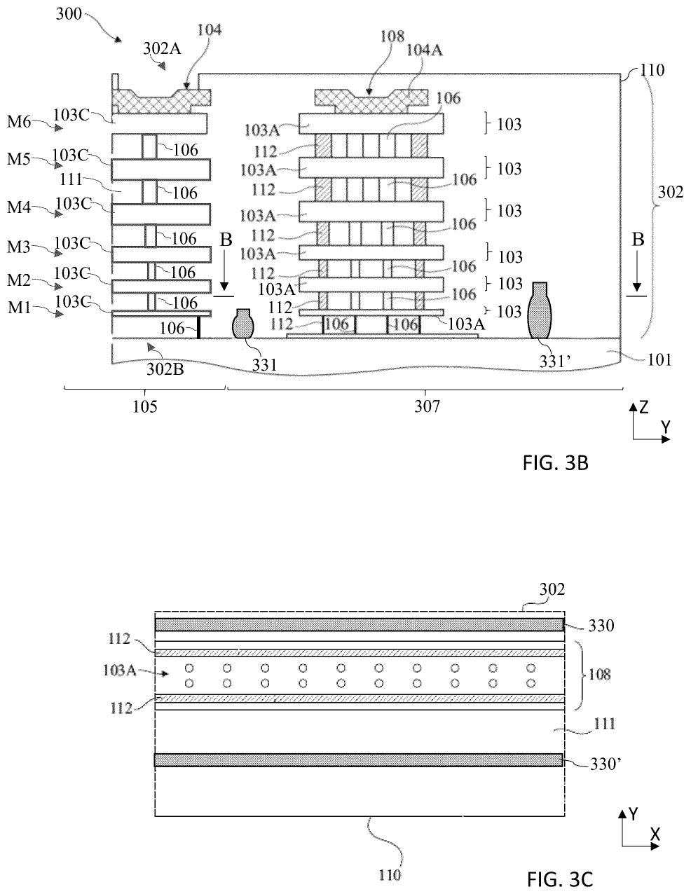

FIG. 3A is a simplified and partial top view illustrating an electronic chip 300 according to another embodiment. FIG. 3B is a simplified and partial cross-section view showing an example of embodiment of the electronic chip of FIG. 3A. FIG. 3C is another simplified and partial cross-section view of the electronic chip of FIG. 3B. The cross-section view of FIG. 3B is obtained along the cross-section plane A-A illustrated in FIG. 3A. The cross-section view of FIG. 3C is obtained along the cross-section plane B-B indicated in FIG. 3B.

The electronic chip 300 of FIGS. 3A, 3B, and 3C has many features in common with the electronic chip 200 of FIGS. 2A, 2B and 2C, and only the differences between the two electronic chips 200 and 300 are detailed in the following description.

The electronic chip 300 of FIGS. 3A, 3B, and 3C differs from the electronic chip 200 of FIGS. 2A, 2B, and 2C mainly in that the cavities coupled together are filled with a conductive material, preferably a metallic material, such as tungsten or copper, forming conductive regions 331, 331′ in seal ring 307. Like cavities 231, 231′, conductive regions 331, 331′ are coupled together, forming a conductive ring-shaped wall 330, 330′ in seal ring 307 around circuit region 105. Each conductive region 331, 331′ is preferably in one piece. The conductive ring-shaped wall is preferably in one piece. It can also be spoken of a continuous ring-shaped wall. When reference is made to a “one-piece” element, reference is made to an element that holds together in one piece, with no division, no break in shape and material.

Such a conductive ring-shaped wall enables to prevent the propagation of cracks. Indeed, in a sealing element which comprises portions of conductive layers coupled together by vias, the interface between a via and a conductive layer is potentially brittle and may be a source of cracking and/or of crack propagation. However, each conductive region is made of a single conductive material and thus comprises no interface, and thus no brittleness, and the conductive ring-shaped wall formed by the conductive regions coupled together thus forms a continuous wall all around the circuit region and which is capable of opposing the propagation of cracks.

Advantageously, conductive regions 331, 331′ extend at least all the way to the interface between the vias 106 and the conductive layers 103 of two successive metallization levels, for example the first metallization level M1 and the second metallization level M2, so as to block the progression of cracks that would form or propagate at this interface.

There have been shown as an example conductive regions 331 which are formed at the first metallization level M1, thus forming a conductive ring-shaped wall 330 in seal ring 307 at the first metallization level M1. Cracks often occurring at the first metallization level, such a configuration may be sufficient to prevent the propagation of cracks to the circuit region 105 of chip 300. Further, this enables not to burden the manufacturing method, knowing that it can be based on a metal-filled air-gap forming process, which may be already provided in another region of the interconnection structure, for example in circuit region 105, for example at the first metallization level M1.

But this example is not limiting, and there may be formed conductive regions 331′, which extend all the way to the second metallization level M2 as illustrated, or even all the way to a higher metallization level, or even to the upper metallization level (M6 in the example shown), thus forming a conductive ring-shaped wall 330′ in seal ring 307 which extends beyond the first metallization level M1.

Further, there have been shown conductive regions 331, 331′ which reach semiconductor layer 101, which is not always necessary. As a variant, the conductive regions may be at a non-zero distance from semiconductor layer 101, for example end in insulating layer 111, which may form a more robust structure than with conductive regions 331, 331′ which end at semiconductor layer 101.

The other features described in relation with FIGS. 1A, 1B, and 1C may apply to the electronic chip 300 of FIGS. 3A, 3B, and 3C.

In particular, in FIGS. 3A, 3B, and 3C, a single sealing element 108 has been shown, knowing that seal ring 307 may comprise a plurality of sealing elements in interconnection structure 302. For example, seal ring 307 may comprise one or a plurality of sealing elements which do not extend all the way to the upper metallization level, or even a plurality of sealing elements which extend all the way to different metallization levels. For moisture protection, a sealing element preferably extends all the way to the upper metallization level. Further, in FIGS. 3A, 3B, and 3C, no crack sensor has been shown, but the seal ring 307 of chip 300 may comprise one or a plurality of crack sensors, similarly to what has been described in relation with FIGS. 1A, 1B, and 1C. Further, seal ring 307 may comprise one or a plurality of crack sensors which do not necessarily extend all the way to the upper metallization level, or even a plurality of crack sensors which extend all the way to different metallization levels.

The embodiments of FIGS. 2A to 2C and 3A to 3C may be combined. For example, the seal ring may comprise a continuous ring-shaped cavity and a conductive ring-shaped wall, the continuous ring-shaped cavity and the conductive ring-shaped wall being for example substantially concentric.

Further, in combination with one or a plurality of the described embodiments, and similarly to what is described in the seal ring, the interconnection structure may comprise, in the circuit region, other cavities coupled together between adjacent conductive tracks of the interconnection structure, forming another continuous cavity between the adjacent conductive tracks, at least at the first metallization level of the interconnection structure. The interconnection structure may also comprise, in the circuit region, other cavities coupled together between adjacent conductive tracks of the interconnection structure, these other cavities coupled together being filled with a metallic material, such as tungsten or copper, forming a continuous conductive region between the adjacent conductive tracks, at least at the first metallization level of the interconnection structure.

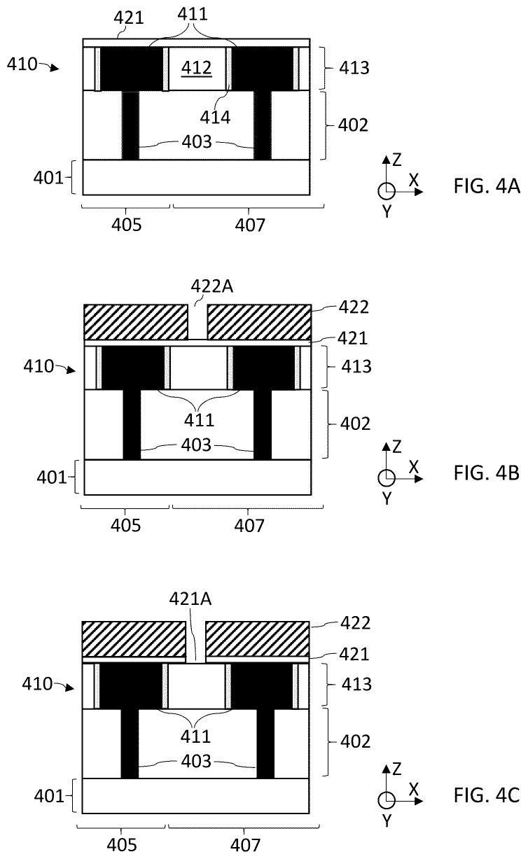

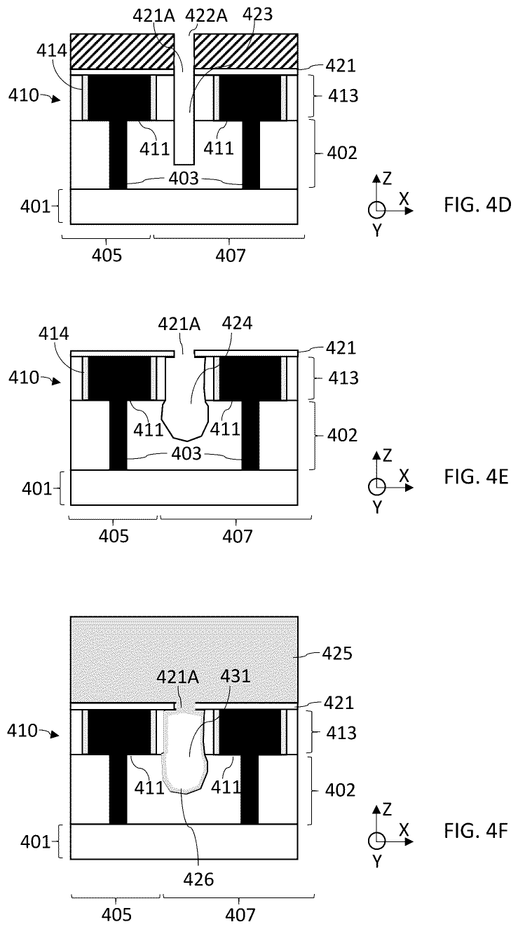

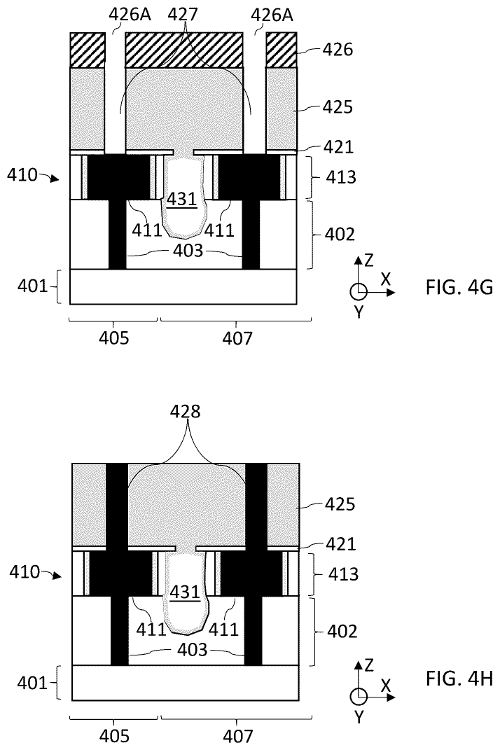

FIG. 4A, FIG. 4B, FIG. 4C, FIG. 4D, FIG. 4E, FIG. 4F, FIG. 4G, and FIG. 4H are cross-section views schematically and partially showing the structures obtained at the end of steps of an example of a method of manufacturing an electronic chip according to an embodiment. The obtained electronic chip is similar to the electronic chip 200 shown in FIGS. 2A, 2B, and 2C, FIG. 4H for example showing a portion of electronic chip 200.

The structure shown in FIG. 4A comprises a first metallization level 410 of a future interconnection structure of a future electronic chip. More specifically, FIG. 4A illustrates a portion of an interconnection structure comprising a seal ring region 407, intended to comprise a seal ring, around a circuit region 405. In circuit region 405, electronic circuits are formed inside and on top of a semiconductor layer 401. The first metallization level 410 is arranged above semiconductor layer 401. In certain embodiments, semiconductor layer 401 corresponds to a semiconductor substrate, for example made of silicon, or to the semiconductor layer of a silicon-on-insulator (SOI) substrate.

Semiconductor layer 401 extends along a main XY plane.

An insulating layer 402, for example a pre-metal dielectric layer, or PMD layer, is formed on semiconductor layer 401. In certain embodiments, PMD layer 402 comprises a silicon oxide, such as silicon dioxide (SiO₂). In other embodiments, PMD layer 402 comprises a silicon phosphide glass, known by the abbreviation “PSG” (Phospho-Silicon Glass), or a silicon borophosphide glass, known by the abbreviation “BPSG” (Borophospho-Silicon Glass). However, PMD layer 402 may comprise a combination of a plurality of these materials, or any other suitable material.

Conductive vias 403 are formed through PMD layer 402 all the way to semiconductor layer 401. Conductive vias 403 may form vias of the type of the cylindrical vias 106 described in relation with FIGS. 1A to 1C, or form elongated vias in the form of bars or of lines, or even form the conductive ring-shaped strips 112 described in relation with FIGS. 1A to 1C.

The first metallization level 410 comprises conductive elements 411, such as metal tracks or lines (elongated in the Y direction), insulated from one another by dielectric elements, or insulating elements 412. These insulating elements 412 altogether form an insulating layer 413 (first insulating layer). Insulating layer 413 may be referred to as an intermetallic dielectric layer, or IMD layer. Conductive elements 411 are coupled to vias 403, being preferably positioned substantially in line with vias 403.

The first metallization level 410 may be formed by a subtractive process, for example for aluminum conductive elements, or by a Damascene-type process, for example for copper conductive elements.

An example of a subtractive process is described in the following. A conductive layer, for example made of aluminum, is deposited on PMD layer 402 and vias 403. Then, the conductive layer is etched through an etch mask, for example obtained by photolithography, the etching forming openings running through the conductive layer all the way to PMD layer 402. The etch mask is sized so that the remaining portions of the conductive layer, forming conductive elements 411, are positioned substantially in line with vias 403. The etch mask is then removed. A protection layer 414 may then be deposited to cover at least the side walls of conductive elements 411, the protection layer may be made of a nitride, such as silicon nitride, or any other suitable material. Then, an IMD layer 413 is formed at least to fill the openings between conductive elements 411, forming insulating elements 412. IMD layer 413 comprises, for example, a silicon oxide, such as silicon dioxide (SiO₂), or any other dielectric material. Excess portions of IMD layer 413 above the conductive layer may then be removed by means of a planarization such as a CMP.

An example of a Damascene process is described in the following. An IMD layer 413 is deposited on PMD layer 402 and vias 403. The IMD layer may be similar to the above-described IMD layer. Then, IMD 413 layer is etched through an etch mask, obtained for example by photolithography, forming openings running through IMD layer 413. The remaining portions of IMD layer 413 form insulating elements 412. The etch mask is sized so that the openings in IMD layer 413 are positioned substantially in line with vias 403. Then, the etch mask is removed. A protection layer 414 may then be deposited in the openings of IMD layer 413, so as to cover at least the side walls of the openings. The protection layer may be similar to the above-described protection layer. A barrier layer may be formed in the openings, so as to cover the side walls and the bottoms of the openings. The barrier layer comprises a suitable conductive material such as tantalum, tantalum nitride, titanium, titanium nitride, or a combination of a plurality of these materials. Then, a layer made of a conductive material, for example of copper, is formed at least to fill the openings between insulating elements 412, forming conductive elements 411 with the barrier layer when it is provided. Excess portions of the conductive layer above insulating elements 412 may be removed by means of a planarization such as a CMP.

In both techniques, protection layer 414 is present on the flanks of conductive elements 411, which can protect conductive elements 411 during subsequent manufacturing steps, such as an etching to form cavities as described hereafter.

As can be seen in FIG. 4A, a protection layer 421 is formed on the first metallization level 410, that is, on conductive elements 411 and IMD layer 413. Protection layer 421 may be similar to the above-described protection layer 414.

FIG. 4B shows a structure obtained at the end of the forming of an etch mask 422 on protection layer 421. Etch mask 422 may be obtained by a photolithography technique, and it comprises an opening 422A running therethrough. A single opening 422A has been shown in FIG. 4B, but there are usually a plurality of openings at least in the Y direction.

FIG. 4C shows a structure obtained at the end of the etching of a portion of protection layer 421 through the opening 422A of etch mask 422, the etched portion forming an opening 421A in protection layer 421. This etching is, for example, a dry etching, of plasma etching type.

FIG. 4D shows a structure obtained at the end of the etching of a port 423 (first port) running through IMD layer 413 all the way into PMD layer 402, between conductive elements 411, in seal ring region 407. The etching is performed through the opening 422A of etch mask 422 and the opening 421A of protection layer 421. port 423 may be formed by means of a suitable anisotropic etching, such as a dry etching, for example, of plasma etching type. The diameter of port 423 may substantially correspond to the diameter of opening 421A in protection layer 421.

The etch steps described in relation with FIGS. 4C and 4D may be carried out in a single step.

Port 423 does not extend all the way to semiconductor layer 401, that is, it ends in PMD layer 402.

Etch mask 422 is then removed.

FIG. 4E shows a structure obtained at the end of the widening of port 423 by etching, so as to form an open cavity 424 in IMD layer 413 and PMD layer 402 between two conductive elements 411, and possibly between two vias 403. The opening of open cavity 424 corresponds to the opening 421A of protection layer 421. Open cavity 424 may be formed by means of a suitable isotropic etching, advantageously selective of the material of IMD layer 413 and of PMD layer 402 with respect to the material of protection layer 421, to avoid etching protection layer 421. In certain embodiments, the isotropic etching is a wet etching, for example performed with hydrofluoric acid (HF), for example HF in vapor form, hydrochloric acid (HCl), potassium hydroxide (KOH), tetramethylammonium hydroxide (TMAH), sodium hydroxide (NaOH), nitric acid (HNO₃), buffered oxide etch (BOE), or a mixture of a plurality of these products.

The diameter of port 423 may enable to define the dimensions of open cavity 424. For example, the larger the diameter of port 423, the larger the average diameter of open cavity 424 can be. The diameter of port 423 is however generally limited by the next step, which consists in closing opening 421A, and thus open cavity 424, without for all this sealing it.

The protection layer 414 which is located on the side walls, or flanks, of conductive elements 411 may advantageously protect conductive elements 411 during the anisotropic etching and/or the isotropic etching.

FIG. 4F shows a structure obtained at the end of the forming of an insulating layer 425 (second insulating layer), which may be referred to as an intermetallic dielectric layer, or IMD layer, on protection layer 421 and on the opening of open cavity 424, so as to close this open cavity, forming a closed cavity referred to as cavity 431. IMD layer 425 may be formed by using materials and methods similar to those of IMD layer 413 as described hereabove. By running through the opening 421A of protection layer 421, the dielectric material of IMD layer 425 can cover the inner surfaces of cavity 431 before closing open cavity 424, forming an inner coating 426 in cavity 431.

The cross-sections of FIGS. 4C, 4D, 4E, 4F respectively show a single opening 421A, a single port 423, a single open cavity 424, and a single cavity 431, but there are a plurality of openings 421A, a plurality of ports 423, and thus a plurality of cavities 431 coupled together in the Y direction. Thus, the cavities 431 between conductive elements 411 are coupled together, forming a continuous extended cavity. This may form a continuous ring-shaped cavity such as the continuous ring-shaped cavity 230 described in relation with FIGS. 2A, 2B, and 2C, since cavities 431 are coupled together all along the periphery of the electronic chip around circuit region 405. The widening of ports 423 is thus advantageously performed in such a way that open cavities 424 can be coupled together, then forming cavities 431 coupled together between conductive elements 411.

The cross-sections of FIGS. 4C, 4D, 4E, and 4F respectively show a single opening 421A, a single port 423, a single open cavity 424, and a single cavity 431 between the two conductive elements 411 in the X direction. This cross-section corresponds to an example, and there could be a plurality of openings 421A, a plurality of ports 423, and then a plurality of adjacent cavities 431 coupled together, between the two conductive elements 411 in the X direction.

FIGS. 4G and 4H show an example of forming of vias 428 coupling the conductive elements 411 of the first metallization level 410 (M1) to other conductive elements of a second metallization level (not shown).

FIG. 4G shows a structure obtained at the end of the forming of an etch mask 426 on IMD layer 425, followed by the etching of IMD layer 425 and of protection layer 421 to form ports 427 running through these layers 425, 421 in line with conductive elements 411.

Etch mask 426 may be obtained by a photolithography technique, and openings 426A in etch mask 426 may be formed in line with conductive elements 411 so that ports 427 are coupled to conductive elements 411, the etching being performed through the openings 426A of etch mask 426.

FIG. 4H shows a structure obtained at the end of the filling of ports 427 with a conductive material, preferably a metallic material, which for example comprises tungsten with the prior forming of a Ti/TiN type barrier layer, or copper with the prior forming of a TaN/Ta type barrier layer, forming conductive vias 428.

FIG. 4H may correspond to a partial cross-section along the cross-section plane C-C indicated in FIG. 2A of the interconnection structure 202 of electronic chip 200. For example, cavity 431 may correspond to one of the cavities 231 of FIG. 2B, which are in seal ring 207, and in interconnection structure 202, between circuit region 105 and sealing element 108. The conductive elements 411 and the vias 403, 428 on the left-hand side of FIG. 4H may correspond to a portion of the interconnection structure which is in circuit region 405, the via 403 on the left-hand side then being a contact coupled to an electronic component on semiconductor layer 401. The conductive elements 411 and vias 403, 428 on the right-hand side of FIG. 4H may correspond to a portion of the interconnection structure which is in seal ring region 407, and may correspond to a portion of a sealing element formed in the interconnection structure.

Then, a second metallization level may be formed, by a technique similar to that used to form the first metallization level 410, for example by a subtractive process or by a Damascene-type process, as described in relation with FIG. 4A. Then, other metallization levels may be formed in similar fashion.

If it is desired to obtain cavities which extend at least all the way to the second metallization level, or even to a higher metallization level, the steps described in relation with FIGS. 4A to 4H may be repeated at least once.

The method described in relation with FIGS. 4A to 4H may be adapted to also form, in the circuit region 405 of the chip, other cavities coupled together between adjacent conductive tracks of the interconnection structure, so as to form another continuous cavity between adjacent conductive tracks, at least at the first metallization level of the interconnection structure.

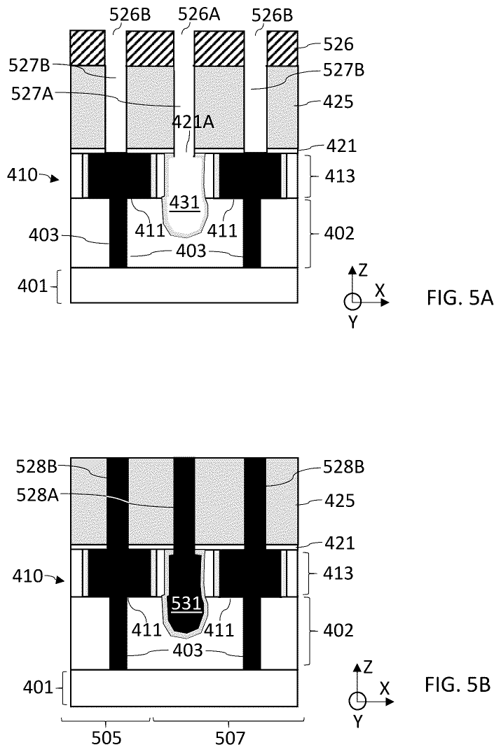

FIG. 5A and FIG. 5B are cross-section views schematically and partially showing structures obtained at the end of steps of a variant of the manufacturing method of FIGS. 4A to 4H. The obtained electronic chip is for example similar to the chip 300 of FIGS. 3A, 3B, and 3C, FIG. 5B for example showing a portion of electronic chip 300.

In particular, FIGS. 5A and 5B show a variant of FIGS. 4G and 4H, in which etch mask 526 comprises a first opening 526A in line with cavity 431, and second openings 526B in line with conductive elements 411. Thus, the etching of IMD layer 425 and of protection layer 421 through etch mask 526 forms a port 527A (second port) which runs through these layers all the way to cavity 431, and are thus coupled to cavity 431, and ports 527B (third ports) which run through these layers to all the way to conductive elements 411 and are thus coupled to conductive elements 411.

A single first opening 526A in line with cavity 431 has been shown, but, as previously indicated, there are a plurality of cavities 431 in the Y direction, and there usually are at least two first openings 526A in line with two different cavities 431.

Ports 527A enable to reopen cavities 431, to fill them with conductive material, and thus fill the continuous extended cavity, or continuous ring-shaped cavity, as described hereafter. Preferably, each port 527A is centered with one of the openings 421A of protection layer 421.

As shown in FIG. 5B, during the filling with conductive material, preferably a metallic material, which for example comprises tungsten, the filling of port 527A enables to fill cavity 431 with the conductive material, forming a conductive region 531, and port 527A forms a first via 528A once filled. A single conductive region 531 has been shown, but, as previously indicated, there are a plurality of cavities 431 coupled together in the Y direction, and thus there are a plurality of conductive regions 531 coupled together in the Y direction. There further generally are at least two first vias 528A in the Y direction.

The filling of ports 527B forms second vias 528B which are coupled to conductive elements 411 and which take part in the interconnection of the conductive elements 411 of the first metallization level 410 with conductive elements of a second metallization level (not shown).

The filling is carried out by means of a suitable deposition technique, such as an ALD technique, or by a PVD or CVD technique, or by electroplating.

Since cavities 431 are coupled together in one or a plurality of directions of the XY plane, conductive regions 531 are also coupled together, forming a continuous conductive wall. This may form a conductive ring-shaped wall such as the conductive ring-shaped wall 330 described in relation with FIGS. 3A, 3B, and 3C, since conductive regions 531 are coupled together all along the periphery of the electronic chip, around circuit region 505.

FIG. 5B may correspond to a partial cross-section along the cross-section plane C-C indicated in FIG. 3A of the first level of the interconnection structure 302 of electronic chip 300. Thus, conductive regions 531 may correspond to the conductive regions 331 of FIG. 3B, which are in seal ring 307, and in interconnection structure 302, between circuit region 105 and sealing element 108. The conductive elements 411 and vias 403, 528B on the left-hand side of FIG. 5B may correspond to a portion of the interconnection structure which is in circuit region 505, in which case the via 403 on the left-hand side may be a contact coupled to an electronic component on semiconductor layer 401. The conductive elements 411 and the vias 403, 528A, 528B on the right-hand side of FIG. 5B may correspond to a portion of the interconnection structure which is in seal ring region 507, and may correspond to a portion of a sealing element formed in the interconnection structure.

Not all the cavities 431 of a single continuous extended cavity are necessarily coupled to a first port 527A. Indeed, since the cavities 431 of a single continuous extended cavity are coupled together, it may be sufficient to have only two ports 527A to fill cavities 431 with conductive material, for example a first inlet port for the conductive material and a first outlet port for the conductive material. However, for example, according to the length of the continuous extended cavity, more than two ports 527A may be provided so that it can be properly filled.

Then, a second metallization level may be formed, by a technique similar to that used to form the first metallization level 410, for example by a subtractive process or by a Damascene-type process, as described in relation with FIG. 4A. Then, other metallization levels may be formed in similar fashion.

If it is desired to obtain conductive regions which extend at least all the way to the second metallization level, or even all the way to a higher metallization level, the steps described in relation with FIGS. 4A to 4F, 5A, 5B may be repeated at least once.

The method described in relation with FIGS. 5A and 5B may be adapted to also form, in the circuit region 505 of the chip, other cavities coupled together between adjacent conductive tracks of the interconnection structure, and then fill these other cavities coupled together with a metallic material so as to form a continuous conductive region between adjacent conductive tracks, at least at the first metallization level of the interconnection structure.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

What is claimed is:

1. An electronic chip delimited by an edge, the electronic chip comprising:
a semiconductor layer extending along a main plane;
an interconnection structure positioned above the semiconductor layer; and
a seal ring arranged in the interconnection structure between the edge of the electronic chip and an electronic circuit region of the electronic chip, the seal ring comprising:
a plurality of cavities coupled together to form at least one continuous ring-shaped cavity around the electronic circuit region; and/or
a plurality of conductive regions coupled together to form at least one conductive ring-shaped wall around the electronic circuit region.

2. The electronic chip according to claim 1, wherein the interconnection structure comprises:
a plurality of metallization levels, each comprising a conductive layer, the conductive layers of two successive metallization levels being coupled together by conductive vias and/or conductive strips of the interconnection structure; and
insulating layers in which the conductive layers, and the conductive vias and/or the conductive strips are embedded;
wherein the interconnection structure is coupled to the semiconductor layer by another conductive via and/or of an electrical contact.

3. The electronic chip according to claim 1, wherein the cavities and/or the conductive regions extend at least to a first metallization level of the interconnection structure.

4. The electronic chip according to claim 1, wherein the cavities and/or the conductive regions extend at least to an interface level between conductive vias and conductive layers of two successive metallization levels of the interconnection structure.

5. The electronic chip according to claim 4, wherein the cavities and/or the conductive regions extend at least to the interface level between the conductive vias and the conductive layers of first and second metallization levels of the interconnection structure.

6. The electronic chip according to claim 1, wherein the cavities and/or the conductive regions extend to the semiconductor layer.

7. The electronic chip according to claim 1, wherein the cavities and/or the conductive regions end at a non-zero distance from the semiconductor layer.

8. The electronic chip according to claim 1, wherein the conductive regions are substantially tungsten.

9. The electronic chip according to claim 1, wherein the seal ring comprises a sealing element comprising a conductive ring-shaped plate in each metallization level of the interconnection structure, two conductive ring-shaped plates of two successive metallization levels being coupled together in a direction perpendicular to the main plane by a conductive ring-shaped strip.

10. The electronic chip according to claim 9, wherein the at least one continuous ring-shaped cavity comprises a first continuous ring-shaped cavity between the electronic circuit region and the sealing element and/or a second continuous ring-shaped cavity between the sealing element and the edge of the electronic chip.

11. The electronic chip according to claim 9, wherein the at least one conductive ring-shaped wall comprises a first conductive ring-shaped wall between the electronic circuit region and the sealing element and/or a second conductive ring-shaped wall between the sealing element and the edge of the electronic chip.

12. The electronic chip according to claim 1, further comprising, in the electronic circuit region, other cavities coupled together and/or other conductive regions coupled together, between second two adjacent conductive elements of the interconnection structure.

13. A method of manufacturing an electronic chip, the method comprising:
providing a structure comprising a semiconductor layer and a first metallization level of an interconnection structure over the semiconductor layer, the structure having an electronic circuit region comprising electronic circuits formed inside and on top of the semiconductor layer, and a seal ring region around the electronic circuit region, and the first metallization level comprising conductive elements of a conductive layer insulated from one another by insulating elements of a first insulating layer;
forming first ports in the seal ring region through the first insulating layer between first two adjacent conductive elements among the conductive elements;
widening the first ports by etching, so as to form in the seal ring region open cavities coupled together around the electronic circuit region; and
forming a second insulating layer over the open cavities and the first insulating layer, so as to close the open cavities, thereby forming cavities coupled together around the electronic circuit region, the cavities coupled together forming at least one continuous ring-shaped cavity around the electronic circuit region.

14. The method according to claim 13, further comprising, prior to the forming the first ports, depositing a protection layer over the first insulating layer and the conductive elements, followed by forming openings by etching in the protection layer, the first ports being formed in line with the openings.

15. The method according to claim 13, further comprising:
forming at least two second ports by etching in the second insulating layer to at least two of the cavities in the seal ring region; and
filling the second ports with a conductive material, so as to fill the cavities, thereby forming conductive regions coupled together, and thereby at least one conductive ring-shaped wall around the electronic circuit region.

16. The method according to claim 15, wherein the filling of the second ports also forms first conductive vias coupled to the conductive ring-shaped wall.

17. The method according to claim 15, further comprising:
forming third ports by etching in the second insulating layer, each third port extending to one of the conductive elements; and
filling the third ports with the conductive material, thereby forming second conductive vias coupled to the conductive elements.

18. The method according to claim 17, wherein the conductive material is substantially tungsten.

19. The method according to claim 17, wherein the forming the third ports is performed at a same time as the forming the second ports, and/or the filling the third ports is performed at a same time as the filling the second ports.

20. The method according to claim 13, further comprising forming, in the electronic circuit region, other cavities coupled together, and/or other conductive regions coupled together, between two adjacent conductive elements of the interconnection structure.
